(19) United States
(12) Patent Application Publication
(10) Pub. No.: US 2012/0100695 A1
(43) Pub. Date: Apr. 26, 2012

(54) MANUFACTURING METHOD OF SEMICONDUCTOR DEVICE

(75) Inventors: YASUHARU SUGAWARA, KANAGAWA-KEN (JP); HIDEFUMI YASUDA, KANAGAWA-KEN (JP); SHUJI ITONAGA, KANAGAWA-KEN (JP)

(73) Assignee: KABUSHIKI KAISHA TOSHIBA, TOKYO (JP)

(21) Appl. No.: 13/250,957

(22) Filed: Sep. 30, 2011

(30) Foreign Application Priority Data
Oct. 21, 2010 (JP) 2010-236182

(51) Int. Cl. H01L 21/78

(52) U.S. Cl. 438/463; 257/E21.599

(57) ABSTRACT

A manufacturing method of a semiconductor device according to one embodiment includes attaching a front-side protecting member to a first main surface of a semiconductor wafer having an element region formed therein; laser-dicing the semiconductor wafer by applying a laser beam from a second main surface opposite to the first main surface of the semiconductor wafer; forming a backside metal film on the second main surface of the semiconductor wafer; and pressing a spherical surface against the front-side protecting member to expand the front-side protecting member and form individually divided semiconductor chips having the backside metal film attached thereto.

### CROSS REFERENCE TO RELATED APPLICATION

This application is based upon and claims the benefit of priority from Japanese Patent Application No. 2010-236182, filed on Oct. 21, 2010, the entire contents of which are incorporated herein by reference.

### BACKGROUND

In dicing process of a semiconductor wafer, a backside grinding or backside thinning is provided before dicing in order to dice the semiconductor chips into chips easily.

A laser dicing method capable of reducing a street area such as a dicing region is widely used for various semiconductor devices.

The laser dicing method has its difficulty, when a metal film is formed on a backside of a semiconductor wafer, in simultaneously dicing the semiconductor wafer and the backside metal film. For this reason, in the case of an LED (Light Emitting Diode) that is an optical semiconductor element having a backside metal film formed as a high-reflection film, for example, a substrate of the LED is diced with a laser, the backside metal film is formed as the high-reflection film, and then the substrate is divided into chips.

However, this method suffers from problems in an expanding step, such as peeling off of the high-reflection film that is the backside metal film from a chip edge or connecting of the chips to each other.

### BRIEF DESCRIPTIONS OF THE DRAWINGS

A more complete appreciation of embodiments of the invention and many of the attendant advantages thereof will be readily obtained as the same becomes better understood by reference to the following detailed description when considered in connection with the accompanying drawings.

FIGS. 1-4 are cross sectional views showing a manufacturing process of a semiconductor device in accordance with a first embodiment of the present invention.

FIG. 5A is a cross sectional view of a semiconductor device which has been diced into a chip in accordance with the first embodiment. FIG. 5B is a cross sectional view of a semiconductor device which has been diced into a chip in accordance with a comparative example.

FIGS. 6 and 7 are cross sectional views showing a manufacturing process of a semiconductor device in accordance with a modification of the first embodiment.

FIGS. 8 and 9 are cross sectional views showing a manufacturing process of a semiconductor device in accordance with a second embodiment of the present invention.

FIG. 10 is a cross sectional view of a semiconductor device which has been diced into a chip in accordance with the second embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

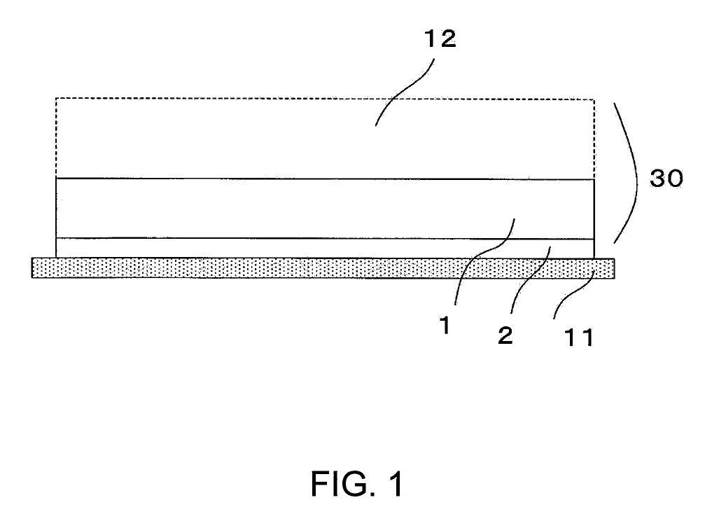

First, description is given of a method for manufacturing a semiconductor device and the semiconductor device according to a first embodiment of the present invention with reference to the drawings. FIGS. 1 to 4 are cross-sectional views showing the steps of manufacturing a semiconductor device. In this embodiment, a semiconductor wafer having an element region formed on its surface is broken by dicing, a backside metal film is formed thereon, and then the wafer is divided into semiconductor chips by use of a pressing part having a spherical shape.

In the method for manufacturing a semiconductor device, as shown in FIG. 1, a semiconductor wafer holding member 11 for protecting semiconductor elements from backside polishing is attached to a first main surface (front side) of a semiconductor wafer 30 having an element region 2 formed on a first main surface (front side) of a substrate 1. Here, the semiconductor element is an LED (Light Emitting Diode). For the substrate 1, for example, an alumina substrate is used. The element region 2 is formed by lamination from an epitaxial layer formed using, for example, a MOCVD method or the like. For the semiconductor wafer holding member 11, a glass substrate such as quartz, for example, is used.

After attaching the semiconductor wafer holding member 11, the semiconductor wafer 30 is held by vacuum suction and subjected to backside polishing and backside mirror-like finishing using a semiconductor wafer backside polishing apparatus (not shown). This step allows the wafer to be polished for the thickness of a backside grinding region 12, thereby thinning the semiconductor wafer 30.

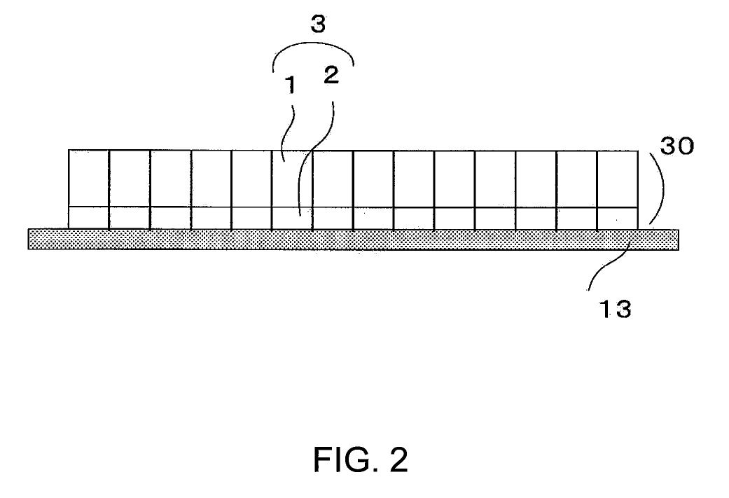

Next, as shown in FIG. 2, a backside protecting member (not shown) is attached to a second main surface (back side) opposite to the first main surface (front side) of the semiconductor wafer 30, and then the semiconductor wafer holding member 11 is peeled off. After the semiconductor wafer holding member 11 is peeled off, a front-side protecting member 13 is attached to the first main surface (front side) of the semiconductor wafer 30, and then the backside protecting member on the second main surface (back side) of the semiconductor wafer 30 is peeled off. For the backside protecting member and the front-side protecting member 13, organic protective tapes, for example, are used.

Thereafter, the pattern shape of the element region 2 is observed from the backside for positioning, and then laser dicing is performed by applying a laser beam onto the second main surface (back side) of the semiconductor wafer 30. The semiconductor wafer 30 is divided into semiconductor chips 3 by the laser dicing. It is preferable that a laser capable of reducing debris or airborne matter and having a short pulse of picosecond or less and a wavelength of 355 nm, which is three times longer than that of an Nd:YAG laser, for example, is used as the laser beam.

Although the laser dicing is used here, the semiconductor wafer 30 may be divided into the semiconductor chips 3 by tearing (separating) using a modifying layer formed by focusing the laser beam inside the semiconductor wafer 30, instead. Moreover, dicing may be performed using a laser microjet method. Furthermore, a front-side protecting member may be used instead of the semiconductor wafer holding member 11. In this case, a step of transferring the protecting member can be omitted, thereby enabling reduction in the number of steps.

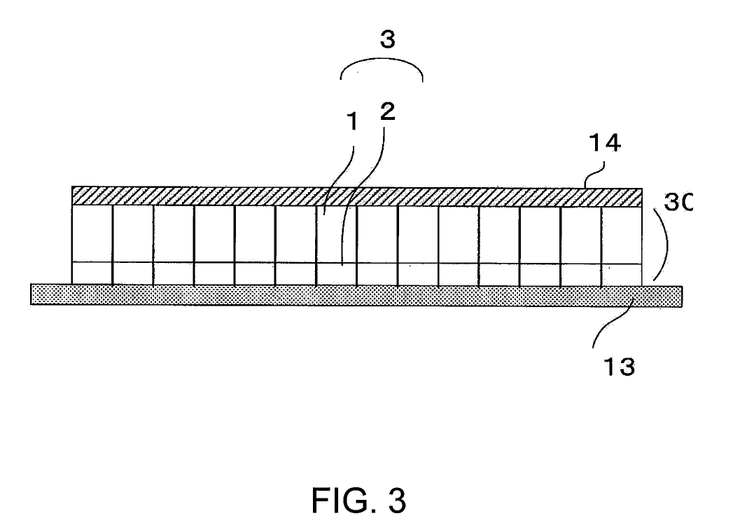

Subsequently, as shown in FIG. 3, a backside metal film 14 is formed as a high-reflection film on the second main surface (back side) of the semiconductor wafer 30. Ag (silver) or the like, for example, is used for the backside metal film 14. In one embodiment, backside metal film 14 is formed using a sputtering method.

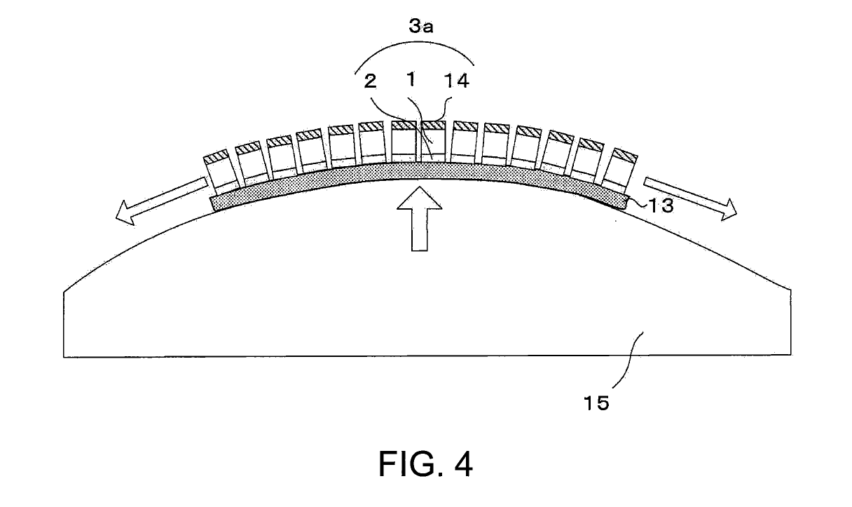

Thereafter, as shown in FIG. 4, a pressing part 15 of an expanding apparatus having a spherical surface is pressed against the front-side protecting member 13 to apply force in an oblique direction to the backside metal film 14, thereby tearing (separating) the backside metal film 14. As a result, the semiconductor wafer is divided into pieces, each of which is a semiconductor chip 3a as a semiconductor device including the substrate 1, the element region 2 and the backside metal film 14. A radius (R) of the pressing part 15 is set within a range of, for example, 30 to 300 mm in consideration of the size of the semiconductor wafer 30. In the expanding step, an ambient temperature is set within a range of, for example, room temperature to 80° C. Since the steps thereafter are performed using a well-known technology, illustration and description thereof are omitted. It should also be understood that because the expanding apparatus has a spherical surface, the backside metal film 14 tears at portions that connect pieces left and right, as shown in the view of FIG. 4, and at portions that connect pieces front and back (not shown in the view of FIG. 4).

By contrast, when the expanding step is performed using a pressing part 15 having a flat surface, peeling off of the backside metal film 14 that is the high-reflection film, pairing in which the chips are connected to each other, or the like occurs. This leads to reduction in yield of the semiconductor backside processing or deterioration in quality of the semiconductor chip as the semiconductor device.

In the first embodiment, the force applied in the oblique direction to the backside metal film 14 formed as the high-reflection film makes the backside metal film 14 easy to break. As a result, peeling off of the backside metal film 14 or pairing can be significantly reduced, and thus desired backside reflection intensity can be secured.

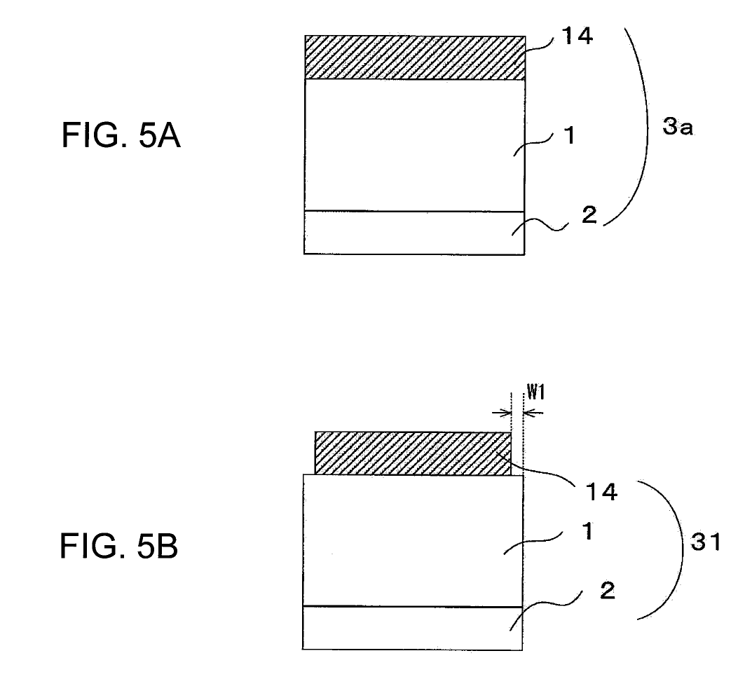

Next, the shape of the semiconductor chip formed is described with reference to FIGS. 5A and 5B. FIGS. 5A and 5B are cross-sectional views each showing a divided semiconductor chip. FIG. 5A shows the semiconductor chip of the first embodiment, while FIG. 5B shows a semiconductor chip of a comparative example.

In the comparative example, as shown in FIG. 5B, in order to prevent peeling off of a backside metal film 14 or pairing, laser dicing is performed from a second main surface (back side) side of a substrate 1 after the backside metal film 14 in a dicing lane portion is removed by etching.

As a result, the backside metal film 14 has its end provided on the inner side by a distance W1 from the ends of the substrate 1 and element region 2. The comparative example requires the steps of forming a resist film and of etching the backside metal film 14, leading to an increase in the number of steps and in a street area.

On the other hand, in the first embodiment, the substrate 1, the element region 2 and the backside metal film 14 have their ends aligned as shown in FIG. 5A. In addition, this embodiment does not require the steps of forming a resist film and of etching the backside metal film 14. That is, the number of steps can be reduced.

As described above, in the method for manufacturing a semiconductor device and the semiconductor device according to the first embodiment, the element region 2 is protected by the front-side protecting member 13 after backside polishing of the semiconductor wafer 30, and then laser dicing is performed by applying the laser beam from the back side of the semiconductor wafer. After the laser dicing, the backside metal film 14 is formed, and then the pressing part 15 is pressed against the front-side protecting member 13 to apply force in the oblique direction to the backside metal film 14, thereby tearing (separating) the backside metal film 14.

As a result, peeling off of the backside metal film 14 formed as the high-reflection film, pairing in which the chips are connected to each other, or the like can be significantly prevented from occurring. Thus, desired backside reflection intensity can be secured.

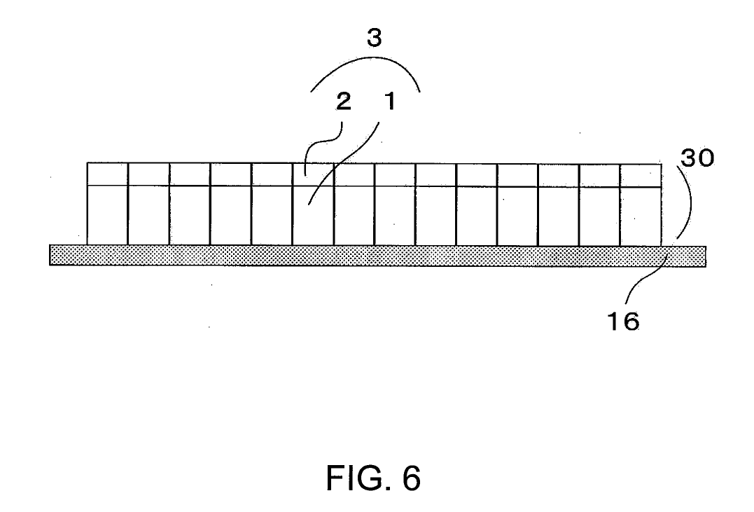

Note that although the laser dicing is performed from the second main surface (back side) of the substrate 1 in the first embodiment, the present invention is not necessarily limited thereto. For example, as shown in FIG. 6, laser dicing may be performed from the first main surface (front side) of the substrate 1 by attaching a backside protecting member to the second main surface (back side) of the substrate 1.

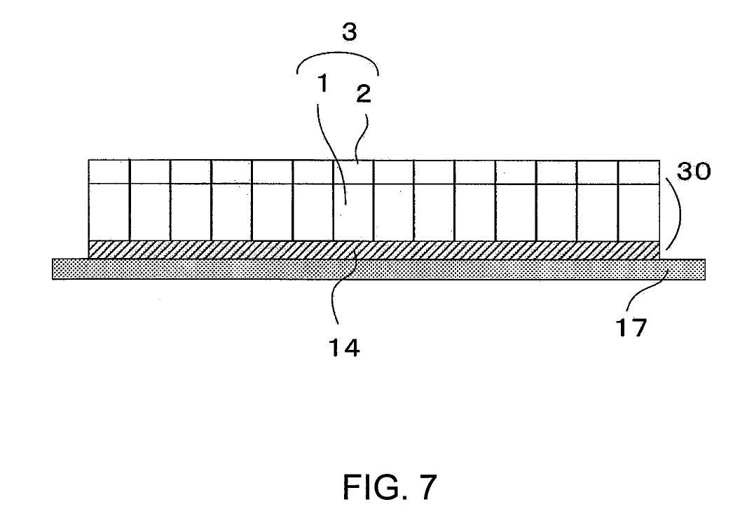

Furthermore, although the front-side protecting member 13 is expanded by pressing the pressing part 15 against the front-side protecting member 13 after the backside metal film 14 is formed on the second main surface (back side) of the substrate 1 in the first embodiment, the present invention is not necessarily limited thereto. For example, as shown in FIG. 7, the front-side protecting member 13 may be expanded by pressing the pressing part 15 against the front-side protecting member 13 after the backside metal film 14 is formed on the second main surface (back side) of the substrate 1 and a backside protecting member 17 is attached.

### Second Embodiment

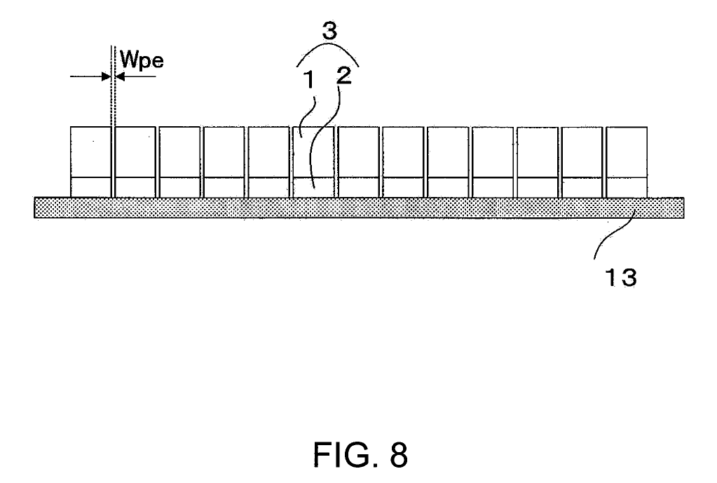

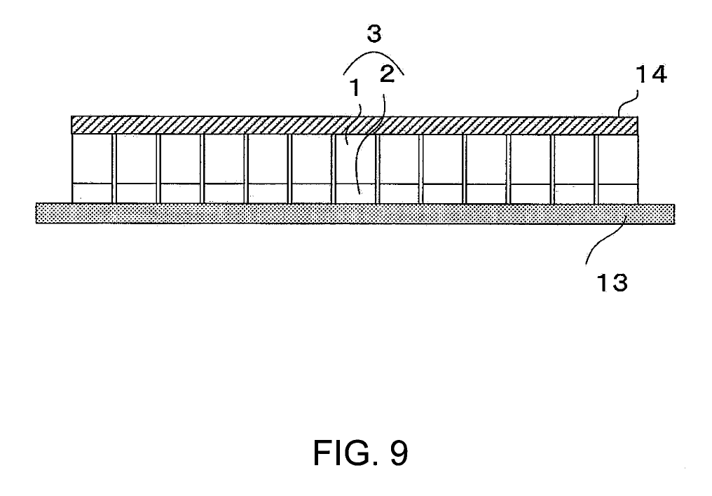

Next, description is given of a method for manufacturing a semiconductor device and the semiconductor device according to a second embodiment of the present invention with reference to the drawings. FIGS. 8 and 9 are cross-sectional views showing the steps of manufacturing a semiconductor device. In this embodiment, a semiconductor wafer having an element region formed on its surface is broken by dicing and is pre-expanded first, then, a backside metal film is formed thereon, and then the wafer is divided into semiconductor chips by use of a pressing part having a spherical shape.

Hereinafter, the same constituent parts as those of the first embodiment are denoted by the same reference numerals, and only different parts are described while description of the same parts is omitted.

As shown in FIG. 8, after laser dicing, a front-side protecting member 13 is expanded in a horizontal direction to separate semiconductor chips 3 from each other by a pre-expand interval Wpe. The pre-expand interval Wpe is preferably set within a range of, for example, 0.5 to 10 μm so that a backside metal film 14 is not formed on side surfaces of the semiconductor chips 3. It should also be understood that the expansion occurs in the horizontal direction so that a gap is formed between pieces that are adjacent left and right, as shown in the view of FIG. 8, and between pieces that are adjacent front and back (not shown in the view of FIG. 8).

Next, as shown in FIG. 9, the backside metal film 14 is formed as a high-reflection film on a second main surface (back side) of a semiconductor wafer 30. Ag (silver) or the like, for example, is used for the backside metal film 14. In one embodiment, backside metal film 14 is formed using a sputtering method. Since steps thereafter are similar to those in the first embodiment, such as the step of pressing using an expanding apparatus having a spherical surface, description thereof is omitted.

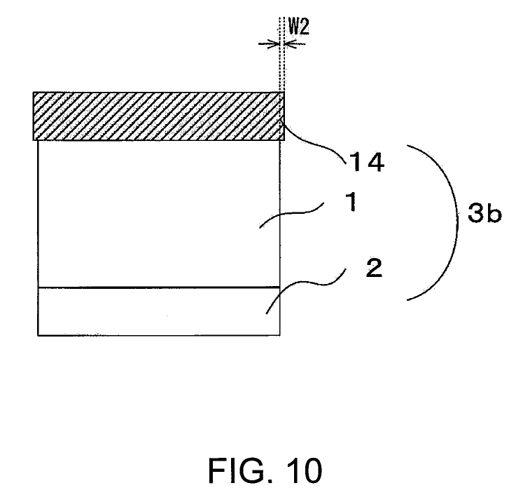

Next, the shape of the semiconductor chip formed is described with reference to FIG. 10. FIG. 10 is a cross-sectional view showing one of the divided semiconductor chips.

As shown in FIG. 10, a semiconductor chip 3b, which is one of the divided semiconductor chips, has the substrate 1 and the element region 2 having their ends aligned. The backside metal film 14 has its end protruding, by a distance W2, relative to the ends of the substrate 1 and the element region 2.

As described above, in the method for manufacturing a semiconductor device and the semiconductor device according to the second embodiment, the element region 2 is protected by the front-side protecting member 13 after backside polishing of the semiconductor wafer 30, and then laser dicing is performed by applying a laser beam from the back side of the semiconductor wafer. After the laser dicing, the front-side protecting member 13 is pre-expanded in the horizontal direction for a predetermined amount. After the pre-expanding, the backside metal film 14 is formed, and then the pressing part 15 is pressed against the front-side protecting member 13 to apply force in an oblique direction to the backside metal film 14, thereby tearing (separating) the backside metal film 14.

As a result, peeling off of the backside metal film 14 formed as the high-reflection film, pairing in which the chips are connected to each other, or the like can be significantly prevented from occurring. Thus, desired backside reflection intensity can be secured.

Note that the embodiments described above are applied to the semiconductor backside processing for dividing a semiconductor wafer into individual LED pieces, but they may be applied instead to a semiconductor element or semiconductor integrated circuit having a backside metal film.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, comprising the steps of:
attaching a front-side protecting member to a first main surface of a semiconductor wafer having an element region formed therein;
dicing the semiconductor wafer;
forming a backside metal film on a second main surface of the semiconductor wafer opposite to the first main surface; and
pressing a curved surface against the front-side protecting member to expand the front-side protecting member and form individually divided semiconductor chips having the backside metal film attached thereto.

2. The method for manufacturing a semiconductor device, according to claim 1, wherein the curved surface is a spherical surface.

3. The method for manufacturing a semiconductor device, according to claim 2, wherein the pressing part has a spherical surface having a radius of 30 to 300 mm.

4. The method for manufacturing a semiconductor device, according to claim 2, wherein portions of the backside metal film between the individually divided semiconductor chips tear when the spherical surface presses against the front-side protecting member to expand the front-side protecting member.

5. The method for manufacturing a semiconductor device, according to claim 2, wherein the spherical surface presses against an entire surface of the front-side protecting member.

6. The method for manufacturing a semiconductor device, according to claim 1, wherein backside metal film is made of Ag.

7. The method for manufacturing a semiconductor device, according to claim 1, wherein the step of dicing the semiconductor wafer includes applying a laser beam from the second main surface.

8. A method for manufacturing a semiconductor device, comprising the steps of:
attaching a front-side protecting member to a first main surface of a semiconductor wafer having an element region formed therein;
forming a modifying layer by focusing a laser beam inside the semiconductor wafer from a second main surface opposite to the first main surface of the semiconductor wafer;
forming a backside metal film on the second main surface of the semiconductor wafer; and
pressing a curved surface against the front-side protecting member to expand the front-side protecting member and form individually divided semiconductor chips having the backside metal film attached thereto.

9. The method for manufacturing a semiconductor device, according to claim 8, wherein the curved surface is a spherical surface.

10. The method for manufacturing a semiconductor device, according to claim 9, wherein the pressing part has a spherical surface having a radius of 30 to 300 mm.

11. The method for manufacturing a semiconductor device, according to claim 9, wherein portions of the backside metal film between the individually divided semiconductor chips tear when the spherical surface presses against the front-side protecting member to expand the front-side protecting member.

12. The method for manufacturing a semiconductor device, according to claim 9, wherein the spherical surface presses against an entire surface of the front-side protecting member.

13. The method for manufacturing a semiconductor device, according to claim 8, wherein backside metal film is made of Ag.

14. A method for manufacturing a semiconductor device, comprising the steps of:
attaching a front-side protecting member to a first main surface of a semiconductor wafer having an element region formed therein;
dicing the semiconductor wafer;
expanding the front-side protecting member in a horizontal direction to separate semiconductor chips individually divided by the laser dicing from each other by a predetermined interval;
forming a backside metal film on a second main surface of the semiconductor wafer opposite to the first main surface; and
pressing a curved surface against the front-side protecting member to expand the front-side protecting member and form individually divided semiconductor chips having the backside metal film attached thereto.

15. The method for manufacturing a semiconductor device, according to claim 14, wherein the curved surface is a spherical surface.

16. The method for manufacturing a semiconductor device, according to claim 15, wherein the pressing part has a spherical surface having a radius of 30 to 300 mm.

17. The method for manufacturing a semiconductor device, according to claim 15, wherein portions of the backside metal film between the individually divided semiconductor chips tear when the spherical surface presses against the front-side protecting member to expand the front-side protecting member.

18. The method for manufacturing a semiconductor device, according to claim 15, wherein the spherical surface presses against an entire surface of the front-side protecting member.

19. The method for manufacturing a semiconductor device, according to claim 14, wherein backside metal film is made of Ag.

20. The method for manufacturing a semiconductor device, according to claim 14, wherein the step of dicing the semiconductor wafer includes applying a laser beam from the second main surface.
